(19) United States
(12) Patent Application Publication
(10) Pub. No.: US 2011/0284053 A1
(43) Pub. Date: Nov. 24, 2011

(54) Rainyday volts 24/7

(76) Inventor: Richard Allen Brewer, St. Charles, MO (US)

(21) Appl. No.: 12/802,147

(22) Filed: May 22, 2010

(51) Int. Cl. H01L 31/052

(52) U.S. Cl. 136/246

(57) ABSTRACT

This utility disclosed herein, is unique because it produces electricity twenty four (24) hours a day. It uses light emitting diodes (LED) and thin-film photovoltaic (PV) solar cells. The PV solar cells and the LED lights are self-contained in a rectangular plastic housing. When energized, the LED lights produce lights that are absorbed by the thin filmed solar cells and converted into Direct Current (DC) electricity. The PV panel, together with other electric devices or appliances produce electricity that is used for the home, farm, and business. This invention uses existing technology in combinations not used previously.

### CROSS-REFERENCE TO RELATED APPLICATIONS

This application claims all rights and privileges of U.S. provisional application—Ser. No. 61/21,244 filed May 28, 2009.

### SEQUENCE LISTING: NONE

### BACKGROUND

Solar energy refers primarily to the use of solar radiation for practical ends. Sunlight can be converted into electricity using photovoltaic cells (PV). Photovoltaic cells at this point in time are only practical in daylight hours. Solar power requires a back-up supply system, to compliment the solar power wind turbines or batteries are necessary. Back-up electricity is excessively expensive.

### BRIEF SUMMARY OF INVENTION

The preferred embodiment of this invention disclosed herein uses a plurality of photovoltaic thin-film solar cells. The many comparable thin-film PV cells now developed are flexible, light-weight, and easily manufactured. The thin film. PV cells are less costly, and are adaptable to countless shapes. Silicone based PV cells are limited in application in confined spaces. Another preferred embodiment of this invention uses a plurality of light-emitting diodes (LED) that emit a white light. Recent developments have improved efficiency in brightness, life-expectancy, and less heat as apposed to incandescent and fluorescent lighting fixtures. Another improved embodiment for this said invention is a housing suitable for receiving and attaching therein the LEDS and PV cells. The said housing is made of recycled plastic. Another preferred embodiment of this invention is a rectangular shaped housing. Installation and investment costs are returned in less time, when used with a grid-tie bi-directional electric meter. Off-grid electricity is also attainable.

### DETAILED DESCRIPTION OF INVENTION

One preferred embodiment of this invention is presented in

FIG. 6 is a plurality array of light-emitting diodes (LEDS) that is secured to the inside of the housing of FIG. 6. Recent improvement in development and the manufacturing of LEDS have produced a superior product. LEDS are brighter, long lasting, less expensive, and emit less heat than incandescent or fluorescent lighting.

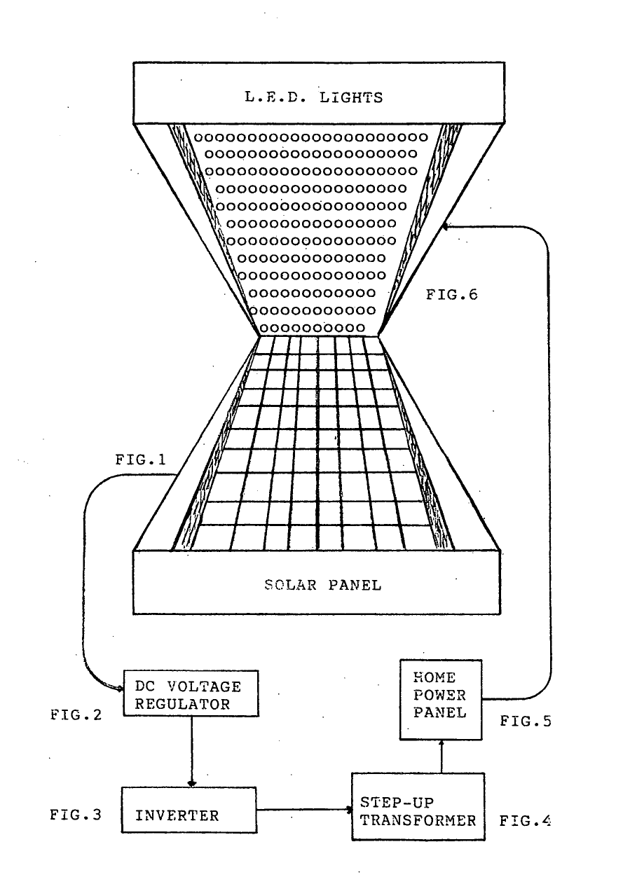

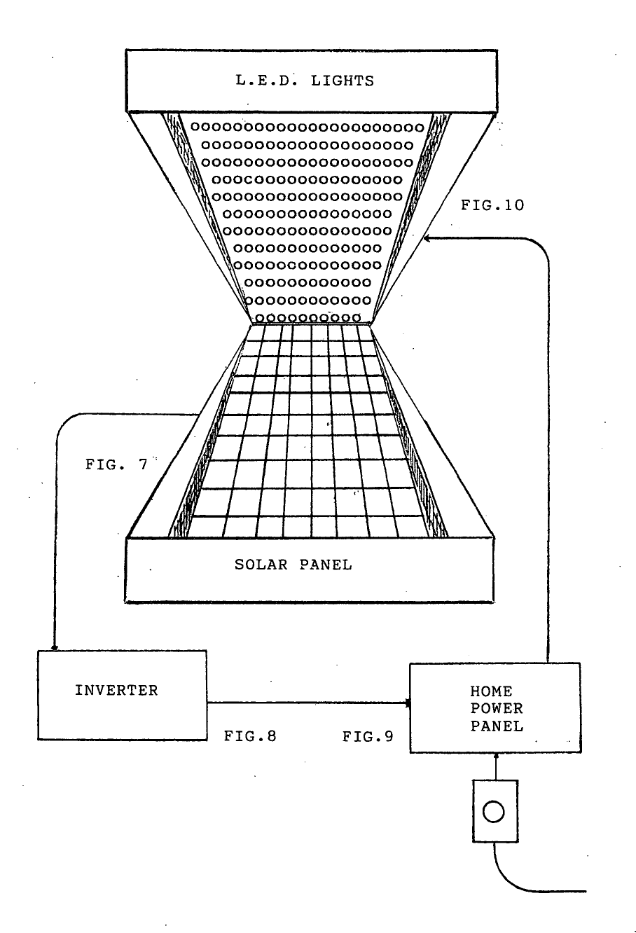

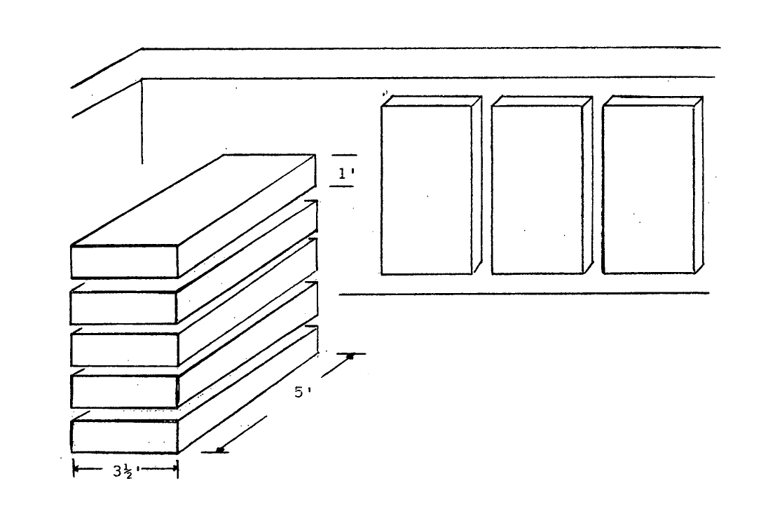

Another preferred embodiment is the application of thin-film photovoltaic cells (PV). FIG. 1 illustrates a plurality of PV cells directly opposite the LED lights. The PV cells are secured to the housing or container, and positioned and arranged to receive the light produced by the light-emitting diodes. FIG. 1 also indicates a 100 kilowatt direct current PV system as an example. Most electric utility companies require 100 kilowatt direct current or less, for interconnection of Net Metering electric systems. The direct current of electricity from FIG. 1 is routed or connected to the DC voltage regulator of FIG. 2. A direct current inverter is presented in FIG. 3. Improved DC inverters have self-contained voltage regulators in FIG. 2. The inverter of FIG. 3 converts the DC electricity into alternating current (AC) at sixty (60) cycles a second. The AC electricity is then dispatched to the step-up transformer in FIG. 4. The step-up transformer is an optional appliance used for large office buildings or complexes. The increased AC electricity from the step-up transformer is directed to the structures electric main manifold. Furthermore, the electric main is universally known as a fuse box. From the fuse box or main FIG. 5 the AC electricity is routed throughout the structure and incorporating the light-emitting diodes illustrated in FIG. 6. When a plurality of solar cells are combined in series, voltage is increased. In some circumstances a step-up transformer will not be needed. Thus, when space is not restricted, addition of more PV cells increases voltage. Another preferred embodiment is a rectangular housing. Said housing is made of recycled plastic. The container or housing, encloses the light-emitting diodes and thin-film photovoltaic cells. Depending on space accommodations, cylinders or nearly any other shaped housing, are adaptable. Each housing is approximately three and one half by five feet by one foot (3½×5×1) in dimension. With the use of thin-film PV solar cells the depth or volume of the housing can be reduced, therefore, saving space. One embodiment of the housing secures the light-emitting diodes to the lid or top of the inside of the container. Another embodiment of the housing secures the thin-film photovoltaic cells to the inside base or bottom of the container. This said housing can be mounted anywhere. This said housing can be installed inside a garage, along a wall, or ceiling. This invention can also be placed in the attic or structures like a barn, shed, or cellar. Another preferred embodiment of this invention is in a basement in close proximity to the buildings electric main or fuse box. When installed inside a structure, this invention is afforded even more protection from all the elements of weather, that would cause damage or a malfunction. The longevity of this invention is furthermore increased than the present life span of (25) to thirty (30) years for the PV cells and the LEDS. This said housing container can incorporate either a passive or active cooling system. A plurality of elementary venting holes or longitudinal openings or slits is adequate in most instances. Installation of a thermostat and fan is also an option. This said housing can be mounted vertically on one end along walls for convenient access. This said housing can be stacked one on top of the other resembling shelves or drawers. This is illustrated in drawing #3. Drawing #2 represents the in-house application of this invention. The plurality of PV solar cells in FIG. 7, produce direct current electricity. The DC electricity is directed to the DC inverter in FIG. 8, whereby the electricity is converted to alternating current. The home's electric panel or fuse box FIG. 9, receives the AC electric from the inverter and distributes the electricity throughout the home including the LED lighting array in FIG. 10. One advantage of this said invention over prior art is that it is self-contained. The said housing incorporating the PV solar cells and LEDS are manufactured and assembled off-site. This process is less expensive and quicker to install when delivered to the job site. Another advantage of this said invention is low maintenance. Removing dust is the only requirement for ordinary people. Individual PV solar cells and LED lights and associated appliances that require service are conducted by qualified personnel. One other advantage of this invention is that it can be retro-fitted to existing PV systems by simply adding the housing containing the light emitting diodes. This invention is subject to all local and National Electric Code (NEC) safety regulations. Applicable appliances such as AC and DC disconnects and by-directional electric meters are not listed in the drawings or detailed description. Universal or common hinges, mounting and securing mechanisms, and locks are also not listed in order to preserve simplicity.

This invention is considered “EARTH FRIENDLY”.

Caustic deep-cell batteries are not used. Therefore the carbon footprint is reduced in relationship to manufacturing of said batteries. Thin-film solar cells and light emitting diodes further reduce the carbon footprint during manufacturing. The environment will profit and improve immensely with the application of this invention. Solar power in any form is vital, indispensable, and necessary for our planet. PV power is even better than hydro-electric because the environment is not altered due to man-made reservoirs. Fossil fuels when used to generate electricity contaminate and pollute everything from drinking water to the air we breathe. Nuclear electric power is most threatening and devastating of all. Wind power is not as wholesome as one might think. It, too, changes the environmental landscape. The construction costs outweigh the energy produced from the wind. The return of the investment dollar is very prolonged or lengthy in time. This invention can be incorporated into the existing infrastructure, which is world-wide. Solar farms, for example, are capable of increasing electric power output by simply “stacking” the housing containing the PV solar cells and LEDS. A solar farm occupying one (1) square acre is capable of amplifying electric power output as much as three (3) to ten (10) times the power output it produces today. Maintenance for such a system is dependent on the design.

It is to be understood the above description is to be illustrative and not restrictive. Those skilled in the arts or science upon reviewing the above description will envision the other apparent embodiments. The scope of this invention, therefore, should be determined with reference to the appended claims, along with the full scope of equivalents to which such claims are entitled.

What is claimed is:

1. This invention uses a plurality of solar cells and a plurality of light-emitting diodes that are self-contained in a housing, separate from the other components of the PV system.

2. This invention uses a step-up transformer.

3. Said housing of claim 1 is made of recycled plastic.

4. Said housing of claim 1 is in a preferred shape of a rectangle.

5. Said housing of claim 1 is hinged for opening and closing.

6. Said housing of claim 1 is secured by a plurality of common fasteners when closed.

7. Said housing of claim 1 is vented for cooling.

8. Said housing of claim 1 is cooled with a small electric fan, which is on the inside of said housing.

9. Said housing of claim 1 has thin-film photovoltaic cells secured to the inside of the housing at the base or bottom.

10. Said housing of claim 1 has light-emitting diodes secured to the inside of the housing on the cover or top.

11. Said housing of claim 1 can be retro-fitted to existing solar panels.

12. This invention of claim 1 uses a plurality of light-emitting diodes that produce a white light.
